(19) United States
(12) Patent Application Publication
(10) Pub. No.: US 2026/0055225 A1
(43) Pub. Date: Feb. 26, 2026

(54) RESIN COMPOSITION, CURED PRODUCT OF RESIN COMPOSITION, SEMICONDUCTOR DEVICE, AND ELECTRONIC COMPONENT

(71) Applicant: NAMICS CORPORATION, Niigata-shi, Niigata (JP)

(72) Inventor: Masayoshi OTOMO, Niigata-shi (JP)

(21) Appl. No.: 19/103,122

(22) PCT Filed: Jul. 28, 2023
(86) PCT No.: PCT/JP2023/027728

§ 371 Date: Feb. 11, 2025

(30) Foreign Application Priority Data
Sep. 2, 2022 (JP) 2022-139821

(51) Int. Cl. C08F 290/06; C08F 220/30; C08K 3/08; C08K 5/08; C08K 5/14; H01L 23/00

(52) U.S. Cl. CPC C08F 290/067; C08F 220/301; C08K 3/08; C08K 5/08; C08K 5/14; H01L 24/29; C08K 2003/0806; C08K 2201/001; H01L 2224/2919; H01L 2924/20103; H01L 2924/20104

(57) ABSTRACT

A resin composition that can cure at a relatively low temperature and has a long pot life, a cured product, and a semiconductor device and an electronic component including a cured product are provided. The resin composition includes (A) a radically polymerizable curable resin, (B) an organic peroxide, and (C) a polymerization inhibitor having sublimability. The resin composition further includes (D) electrically conductive particles as necessary.

### CROSS REFERENCE TO RELATED APPLICATIONS

This application is a 371 U.S. National Phase of International Application No. PCT/JP2023/027728, filed on Jul. 28, 2023, which claims priority to Japanese Patent Application No. 2022-139821, filed Sep. 2, 2022. The entire disclosures of the above applications are incorporated herein by reference.

### BACKGROUND

### Technical Field

The present invention relates to a resin composition, a cured product of a resin composition, a semiconductor device, and an electronic component.

### Related Art

With the spread of advanced communication terminals such as smartphones and tablets, there is an increasing demand for various products that are lighter, smaller, and thinner. In addition, the market for IOT (Internet Of Things), where everything is connected to the Internet, is growing rapidly. While various devices, including smartphones, are being developed for IoT applications, one issue is that production at a high temperature is difficult due to member problems, etc. For example, for soldering components, it is necessary to perform joining at a high temperature exceeding 180° C., which causes damage to the members. Therefore, there is a demand for a joining material that can be cured at a low temperature, allowing for joining.

For example, as an electrically conductive adhesive composition that can cure at a temperature of about 150° C. and provides a cured product having low elasticity after curing, JP2016-117860A discloses an electrically conductive resin composition including (a) polyethylene glycol di(meth)acrylate, (b) a radical generator, (c) an electrically conductive filler, and (d) at least one member selected from the group consisting of linear alkanediol di(meth)acrylates, polyester (meth)acrylates, and terminal-modified polybutadiene rubbers.

A resin composition capable of joining members is required to cure at a relatively low temperature, and a resin composition that has a long pot life and can be used for a long period of time is also required.

Thus, an object of the present invention is to provide a resin composition that can cure at a relatively low temperature such as 150° C. or less, and has a relatively long pot life, as well as a cured product, a semiconductor device, and an electronic component.

### SUMMARY

The means for solving the above problems are as follows, and the present invention encompasses the following aspects.

[1] A resin composition including:
(A) a radically polymerizable curable resin;
(B) an organic peroxide; and
(C) a polymerization inhibitor having sublimability.

[2] The resin composition according to [1] above, further including (D) electrically conductive particles.

[3] The resin composition according to [1] or [2] above, in which the organic peroxide (B) includes at least one member selected from the group consisting of dialkyl peroxides, peroxyesters, peroxymonocarbonates, diacyl peroxides, peroxydicarbonates, and peroxyketals.

[4] The resin composition according to any of [1] to [3] above, in which the organic peroxide (B) has a 10-hour half-life temperature of 70° C. or less.

[5] The resin composition according to any of [1] to [4] above, in which the radically polymerizable curable resin (A) contains a compound having a (meth)acryloyl group.

[6] The resin composition according to any of [1] to [5] above, in which the radically polymerizable curable resin (A) contains a bismaleimide compound.

[7] The resin composition according to any of [1] to [6] above, in which the polymerization inhibitor having sublimability (C) includes p-benzoquinone.

[8] A cured product obtained by curing the resin composition according to any of [1] to [7] above.

[9] A cured product obtained by curing the resin composition according to any of [1] to [7] above at 80° C. for 60 minutes, the cured product having a room temperature elastic modulus within a range of 0.005 GPa or more and 7.0 GPa or less.

A semiconductor device including the cured product according to [9] above.

An electronic component including the cured product according to [9] above.

### Advantageous Effects of Invention

According to the present invention, it is possible to provide a resin composition that can cure at a relatively low temperature and has a relatively long pot life, a cured product obtained by curing the same, a semiconductor device including the cured product, and an electronic component including the cured product.

### BRIEF DESCRIPTION OF THE DRAWINGS

FIG. 1 is a gas chromatograph showing the mass spectrum of benzoquinone at room temperature (about 25° C.) measured by a gas chromatograph mass spectrometer (GC-MS) and the mass spectra of benzoquinone heat-treated at 80° C. for 2 minutes, 3 minutes, and 5 minutes, respectively.

### DETAILED DESCRIPTION

Hereinafter, a resin composition according to the present disclosure, a cured product obtained by curing the same, a semiconductor device including the cured product, and an electronic component including the cured product will be described based on embodiments. However, the embodiments shown below are examples for embodying the technical concept of the present invention, and the present invention is not limited to the following resin composition, cured product obtained by curing the same, semiconductor device including the cured product, and electronic component including the cured product.

### Resin Composition

A resin composition according to a first embodiment of the present invention contains (A) a radically polymerizable curable resin (hereinafter also referred to as “component (A)”), (B) an organic peroxide (hereinafter also referred to as “component (B)”), and (C) a polymerization inhibitor having sublimability (hereinafter also referred to as “component (C)”). A resin composition according to a second embodiment of the present invention preferably further contains (D) electrically conductive particles (hereinafter also referred to as “component (D)”).

Resin compositions for adhesives used for camera modules for use in IoT applications such as smartphones, for example, are required to be curable at a low temperature of 80° C. or less. In addition, resin compositions are required to be usable for a long period of time and have a long working life (pot life). In some resin compositions that are curable at a low temperature, radically polymerizable curable resins such as acrylates and methacrylates are used, and, in some cases, a large amount of radical initiator is used to enable curing at a low temperature. When a large amount of radical initiator is used to enable curing at a low temperature of 80° C. or less, the curing reaction may proceed at an unintended temperature, shortening the working life (pot life).

The resin composition according to the first embodiment of the present invention uses the radically polymerizable curable resin (A) that is highly reactive and the organic peroxide (B) that can be used as an initiator for radical polymerization reactions, and also uses, in order to prevent unintended radical polymerization reactions, the polymerization inhibitor having sublimability (C). As a result, a resin composition that cures at a low temperature such as 80° C. or less and has a long pot life can be provided.

Together with the component (A), the component (B), and the component (C), the resin composition may further contain the electrically conductive particles (D). When the resin composition contains the component (D), it can be used as an electrically conductive adhesive for camera modules for smartphones, for example.

The radically polymerizable curable resin (A) imparts curability and adhesion to the resin composition. A radically polymerizable curable resin has a relatively high polymerization rate and thus allows for rapid curing. The radically polymerizable curable resin composition is not particularly limited as long as it has radical polymerizability. The radically polymerizable curable resin preferably contains at least one member selected from the group consisting of a compound having a (meth)acryloyl group, a bismaleimide compound, and a urethane (meth)acrylate compound, or may also contain two or more kinds. The radically polymerizable curable resin (A) preferably contains a compound having a (meth)acryloyl group. The radically polymerizable curable resin (A) preferably contains a bismaleimide compound. The radically polymerizable curable resin (A) used may contain a compound having a (meth)acryloyl group alone or contain the two of a compound having a (meth)acryloyl group and a bismaleimide compound, or may also be a combination of the three of a compound having a (meth)acryloyl group, a bismaleimide compound, and a urethane (meth)acrylate compound, for example. In the case where the cured product obtained by curing the resin composition is required to have stability, such as heat resistance or moisture resistance, and flexibility, the resin composition preferably contains a compound having a (meth)acryloyl group and a bismaleimide compound. In some cases, the cured product formed from the resin composition is required to have moderate elasticity. In the case where the cured product is required to have moderate elasticity, the resin composition preferably contains a urethane (meth)acrylate compound. As used herein, “(meth)acryloyl group” encompasses both a methacryloyl group and an acryloyl group. In addition, as used herein, “(meth)acrylate” encompasses both methacrylate and acrylate.

For the component (A), a compound in liquid form is preferably used. When the compound used for the component (A) is in liquid form, solvents are not required, making it possible to suppress the formation of voids that are likely to be generated due to solvent volatilization during the curing of the resin composition. The presence of voids in the cured product may lead to a decrease in adhesive strength or the formation of cracks. A solid compound may also be used in the case where it can be dispersed in the resin composition so as to suppress the formation of voids.

The amount of radically polymerizable curable resin (A) contained is, relative to 100 parts by mass of the total amount of the resin composition, preferably within a range of 4 parts by mass or more and 90 parts by mass or less, more preferably within a range of 5 parts by mass or more and 50 parts by mass or less, and still more preferably within a range of 7 parts by mass or more and 30 parts by mass or less. When the content of component (A) in the resin composition is within a range of 4 parts by mass or more and 90 parts by mass or less, curing at a relatively low temperature is possible, leading to good workability, and a cured product having relatively low resistance can be obtained. In addition, the amount of radically polymerizable curable resin (A) contained is, relative to 100 parts by mass of the total organic matter content in the resin composition, preferably within a range of 75 parts by mass or more and 99 parts by mass or less, more preferably within a range of 80 parts by mass or more and 98 parts by mass or less, still more preferably within a range of 85 parts by mass or more and 97 parts by mass or less, and particularly preferably within a range of 90 parts by mass or more and 97 parts by mass or less.

The compound having a (meth)acryloyl group may be any compound having a (meth)acryloyl group in the molecule, and may be an alkyl (meth)acrylate in which the alkyl group has a branched structure, such as isobutyl (meth)acrylate or t-butyl (meth)acrylate; an ester of (meth)acrylic acid and an alicyclic alcohol, such as cyclohexyl (meth)acrylate, isobornyl (meth)acrylate, or dicyclopentanyl (meth)acrylate; an ester of (meth)acrylic acid and an aromatic alcohol, such as phenoxyethyl acrylate, or an acrylamide compound such as hydroxyethyl acrylamide. The compound having a (meth)acryloyl group is preferably a monofunctional (meth)acrylate monomer such as phenoxyethyl (meth)acrylate, dicyclopentanyl (meth)acrylate, or isobornyl (meth)acrylate, or a monofunctional acrylamide monomer such as hydroxyethyl acrylamide. In particular, a monofunctional (meth)acrylate monomer is preferable, and, from the viewpoint of imparting flexibility to the cured product, those containing a (meth)acrylate monomer having a glass transition temperature (Tg) of 15° C. or less are more preferable. Meanwhile, when a (meth)acrylate monomer having a glass transition temperature (Tg) of 15° C. or less is contained alone, the inhibition of curing by oxygen on the cured product surface may become prominent, causing unwanted tackiness (stickiness). In this case, it is still more preferable that a (meth)acrylate monomers having a glass transition temperature (Tg) of 15° C. or more is also contained. When a (meth)acrylate monomer having a glass transition temperature (Tg) of 15° C. or more is contained, tackiness resulting from the inhibition of curing by oxygen on the cured product surface can be reduced. The glass transition temperature (Tg) of a (meth)acrylate monomer can be measured as the glass transition temperature (Tg) of its homopolymer by dynamic viscoelasticity measurement (DMA) or a thermomechanical analyzer (TMA). Incidentally, one kind of (meth)acrylate monomer or a mixture of two or more kinds may be used. When the resin composition contains, specifically, a monofunctional (meth)acrylate monomer such as phenoxyethyl (meth)acrylate or dicyclopentanyl (meth)acrylate, as described above, in the case where the cured product is required to have moderate elasticity, the adjustment of the room temperature elastic modulus of the cured product is facilitated, leading to better workability. In the case of a polyfunctional (meth)acrylate monomer having two or more (meth)acryloyl groups in one molecule, it is preferable that a linear C₄ or higher alkylene backbone or a linear C₄ or higher oxyalkylene backbone is present between adjacent (meth)acryloyl groups. When the polyfunctional radical polymerizable monomer has two or more (meth)acryloyl groups in one molecule, and a linear C₄ or higher alkylene backbone or C₄ or higher oxyalkylene backbone is between adjacent (meth)acryloyl groups, the cured product obtained after curing has a low elastic modulus, high elongation, and moderate flexibility. As long as the number of carbon atoms in the linear chain is 4 or more, the alkylene group or oxyalkylene group between adjacent (meth)acryloyl groups may also have a branched chain.

Among compounds having a (meth)acryloyl group, as acrylate monomers, specifically, Light Acrylate PO-A (phenoxyethyl acrylate, manufactured by Kyoeisha Chemical Co., Ltd.), Light Acrylate IB-XA (isobornyl acrylate, manufactured by Kyoeisha Chemical Co., Ltd.), FA-513AS (dicyclopentanyl acrylate, manufactured by Showa Denko Materials Co., Ltd.), and the like can be used. As acrylamide monomers, specifically, HEAA (hydroxyethyl acrylamide, KJ Chemicals Corporation) and the like can be used.

When the component (A) contains a (meth)acrylate monomer or an acrylamide monomer as a compound having a (meth)acryloyl group, relative to 100 parts by mass of the radically polymerizable curable resin (A), the amount of compound having a (meth)acryloyl group contained is preferably within a range of 3 parts by mass or more and 100 parts by mass or less, more preferably within a range of 5 parts by mass or more and 75 parts by mass or less, and still more preferably within a range of 8 parts by mass or more and 60 parts by mass or less. When the content of compound having a (meth)acryloyl group in the component (A) in the resin composition is 3 parts by mass or more, the resin composition has relatively low viscosity and good handleability, leading to improved workability. With a decrease in the content of compound having a (meth)acryloyl group in the component (A) of the resin composition, the crosslink density is prevented from becoming too high, the room temperature elastic modulus of its cured product decreases, and a cured product having moderate elasticity can be obtained.

Any bismaleimide compound may be used as long as it has a chemical structure sandwiched between two maleimide groups. When the resin composition contains a bismaleimide compound, it is possible to obtain a cured product having excellent stability, such as the heat resistance or moisture resistance of the cured product, while maintaining flexibility. The bismaleimide compound preferably has a weight average molecular weight within a range of 500 or more and 7,000 or less, more preferably within a range of 750 or more and 5,500 or less, and still more preferably within a range of 1,000 or more and 3,000 or less. The bismaleimide compound may also be a dimer acid-modified bismaleimide compound. A dimer acid-modified bismaleimide compound has reactive maleimide groups only at both ends, and has no crosslinkable reactive group in the molecular chain sandwiched between two maleimide groups. Therefore, the room temperature elastic modulus of a cured product obtained by curing the resin composition can be kept low, and a cured product having moderate elasticity is obtained. Among compounds having a (meth)acryloyl group, dimer acid-modified bismaleimide compounds have higher hydrolysis resistance as compared with ester compounds having a (meth)acryloyloxy group. In addition, dimer acid-modified bismaleimide compounds have a large alkyl chain in the molecule and are therefore highly hydrophobic. For this reason, a resin composition containing a dimer acid-modified bismaleimide compound has high water resistance and moisture resistance. As used therein, the weight average molecular weight refers to a value obtained by gel permeation chromatography (GPC) using a calibration curve based on standard polystyrene.

As the bismaleimide compound, specifically, liquid BMI-1500, liquid BMI-1700, and solid BMI-3000 (all manufactured by Designer Molecules), which are dimer acid-modified bismaleimide compounds, can be used. As the bismaleimide compound, one kind of bismaleimide compound may be used, and it is also possible to use a mixture of two or more kinds of bismaleimide compounds having different chemical structures.

When the component (A) contains a bismaleimide compound, relative to 100 parts by mass of the radically polymerizable curable resin (A), the amount of bismaleimide compound contained is preferably within a range of 5 parts by mass or more and 40 parts by mass or less, and more preferably within a range of 15 parts by mass or more and 35 parts by mass or less. When the content of bismaleimide compound in the component (A) in the resin composition is less than 5 parts by mass, the strength of a cured product obtained by curing the resin composition may decrease, making it impossible to obtain a cured product having desired strength. When the content of bismaleimide compound in the component (A) of the resin composition is 40 parts by mass or less, the room temperature elastic modulus of its cured product can be maintained low, and a cured product having moderate elasticity can be obtained.

The urethane (meth)acrylate compound preferably contains a urethane (meth)acrylate oligomer having a weight average molecular weight of 1,000 or more and less than 20,000. When the resin composition contains a urethane (meth)acrylate oligomer, the room temperature elastic modulus of a cured product after curing the resin composition can be kept low without impairing the workability and reactivity of the resin composition, and a cured product having moderate elasticity is obtained. The weight average molecular weight of the urethane (meth)acrylate oligomer is preferably 1,000 or more and less than 20,000, more preferably 1,200 or more and 18,000 or less, and still more preferably 1,500 or more and 15,000 or less. One kind of urethane (meth)acrylate oligomer having the same weight average molecular weight may be used alone, and it is also possible to use a mixture of two or more kinds of urethane (meth)acrylate oligomers having different weight average molecular weights from each other. In the case where a urethane (meth)acrylate oligomer having a weight average molecular weight of 20,000 or more is contained in the resin composition, in some cases, the resin composition has increased viscosity and reduced workability, and also the reactivity of the resin composition decreases due to steric hindrance. Therefore, it is preferable that the resin composition does not substantially contain a urethane (meth)acrylate oligomer having a weight average molecular weight of 20,000 or more. As used herein, “not substantially contain” means that the target substance is not intentionally contained in the resin composition, and specifically means that the content of target substance in the resin composition is 0 to less than 0.1 mass %.

As the urethane (meth)acrylate oligomer, specifically, “UN-3320HA” having a weight average molecular weight of 1,500, “MBA-2CZ” having a weight average molecular weight of 1,600, “UN-333” having a weight average molecular weight of 3,000, “UN-6200” having a weight average molecular weight of 6,500, and “UN-6304” having a weight average molecular weight of 13,000 (all manufactured by Negami Chemical Industrial Co., Ltd.), “UV-3200B” having a weight average molecular weight of 10,000 and “UV-3000B” having a weight average molecular weight of 18,000 (all manufactured by Mitsubishi Chemical Corporation), and the like can be used.

When the component (A) contains a urethane (meth)acrylate oligomer as the urethane (meth)acrylate compound, relative to 100 parts by mass of the radically polymerizable curable resin (A), the amount of urethane (meth)acrylate compound contained is preferably within a range of 5 parts by mass or more and 75 parts by mass or less, more preferably within a range of 6 parts by mass or more and 50 parts by mass or less, and still more preferably within a range of 7 parts by mass or more and 30 parts by mass or less. When the content of urethane (meth)acrylate compound in the component (A) in the resin composition is 5 parts by mass or more, the room temperature elastic modulus of a cured product obtained by curing the resin composition can be reduced, and a cured product having moderate elasticity can be obtained. In addition, when the content of urethane (meth)acrylate compound in the component (A) of the resin composition is 75 parts by mass or less, curing at a relatively low temperature is possible, leading to better workability.

The organic peroxide (B) is cleaved at a predetermined temperature to generate an active radical, and this active radical initiates a radical polymerization reaction of the radically polymerizable curable resin (A). The organic peroxide (B) is a radical polymerization initiator. The organic peroxide (B) preferably has a 10-hour half-life temperature of 70° C. or less. When the organic peroxide (B) has a 10-hour half-life temperature of 70° C. or less, the resin composition can be cured at a relatively low temperature, and, for example, in the case where the resin composition is used for an electronic component, it is possible to mount the electronic component on flexible wiring or the like, for example, without causing thermal damage to the electronic component. The organic peroxide (B) preferably has a 10-hour half-life temperature of 30° C. or more and 70° C. or less. When the component (B) has a 10-hour half-life temperature of less than 30° C., in some cases, the reactivity becomes too high, and the stability of the resin composition decreases, making it impossible to obtain the desired pot life. The 10-hour half-life temperature refers to the temperature at which it takes 10 hours for a peroxide to decompose until the amount is reduced by half (½).

In order to achieve the curing of the resin composition at a relatively low temperature such as 80° C. or less, the organic peroxide (B) preferably includes at least one member selected from the group consisting of dialkyl peroxides, peroxyesters, peroxymonocarbonates, diacyl peroxides, peroxydicarbonates, and peroxyketals. The organic peroxide more preferably includes at least one member selected from peroxydicarbonates and peroxyesters. As peroxyesters, compounds having a peroxyneodecanoate structure are preferable.

As the organic peroxide (B), specifically, bis(4-t-butylcyclohexyl) peroxydicarbonate (product name: PEROYL TCP, NOF Corporation, 10-hour half-life temperature: 40.8° C.), 1,1,3,3-tetramethylbutyl peroxyneodecanoate (product name: Luperox 810, ARKEMA Yoshitomi, Ltd., 10-hour half-life temperature: 44° C.), t-amyl peroxyneodecanoate (product name: Luperox 546, ARKEMA Yoshitomi, Ltd., 10-hour half-life temperature: 46° C.), t-butyl peroxyneodecanoate (product name: Luperox 10, ARKEMA Yoshitomi, Ltd., 10-hour half-life temperature: 48° C.), dicetyl peroxydicarbonate (product name: Perkadox 24L, Kayaku Nouryon Corporation, 10-hour half-life temperature: 48° C.), di(sec-butyl) peroxydicarbonate (product name: Luperox 225, ARKEMA Yoshitomi, Ltd., 10-hour half-life temperature: 51° C.), 1,1,3,3-tetramethylbutyl peroxy-2-ethylhexanoate (product name: PEROCTA O, NOF Corporation, 10-hour half-life temperature: 65.3° C.), dilauroyl peroxide (product name: PEROYL L, NOF Corporation, 10-hour half-life temperature: 61.6° C.), and the like can be used.

The amount of component (B) contained in the resin composition is, relative to 100 parts by mass of the radically polymerizable curable resin serving as component (A), preferably within a range of 0.1 parts by mass or more and 30 parts by mass or less, more preferably within a range of 1 part by mass or more and 20 parts by mass or less, and still more preferably within a range of 3 parts by mass or more and 10 parts by mass or less. When the content of component (B) in the resin composition is within a range of 0.1 parts by mass to 30 parts by mass, it reacts sufficiently even at a low temperature such as 80° C. or less. When the content of component (B) in the resin composition is more than 30 parts by mass, unreacted component (B) potentially remains in the cured product, and, due to the remaining component (B), the cured product may generate heat.

A polymerization inhibitor can suppress a radical polymerization reaction and extend the pot life. The organic peroxide (B) is cleaved at a relatively low temperature to generate an active radical, and initiates a radical polymerization reaction of the radically polymerizable curable resin (A). The organic peroxide (B) is potentially cleaved also at ambient temperature (room temperature) such as about 25° C. and initiates an unintended radical polymerization reaction. Use of a polymerization inhibitor makes it possible to suppress unintended radical polymerization reactions at ambient temperature (room temperature) and extend the pot life. In the present invention, (C) a polymerization inhibitor having sublimability is used. As a result, the polymerization inhibitor sublimes and no longer exists at a temperature at which the initiation of a radical polymerization reaction is desired, and a cured product can be obtained by the intended radical polymerization reaction. As used herein, “sublimability” refers to a property of a substance to undergo a phase transition from a solid to a gas (or from a gas to a solid), and means that the substance has such characteristics that when heat-treated, it changes from a solid to a gas and volatilizes. That is, a polymerization inhibitor having “sublimability” does not undergo a phase transition to a liquid and therefore does not have a boiling point. For example, a polymerization inhibitor having such characteristics that a mass spectrum peak in GC-MS reduces by 90% or more through a heat treatment at 80° C. for 2 minutes or more and 5 minutes or less is defined as a “polymerization inhibitor having sublimability”. The polymerization inhibitor having sublimability (C) preferably sublimes at 80° C. or less. The sublimation temperature of the polymerization inhibitor having sublimability (C) is preferably 80° C. or less, and, in order to suppress unintended radical polymerization reactions, the sublimation temperature is preferably 40° C. or more and 80° C. or less, or may also be 45° C. or more and 80° C. or less.

The polymerization inhibitor having sublimability (C) preferably includes p-benzoquinone. The sublimability of p-benzoquinone can be confirmed as follows.

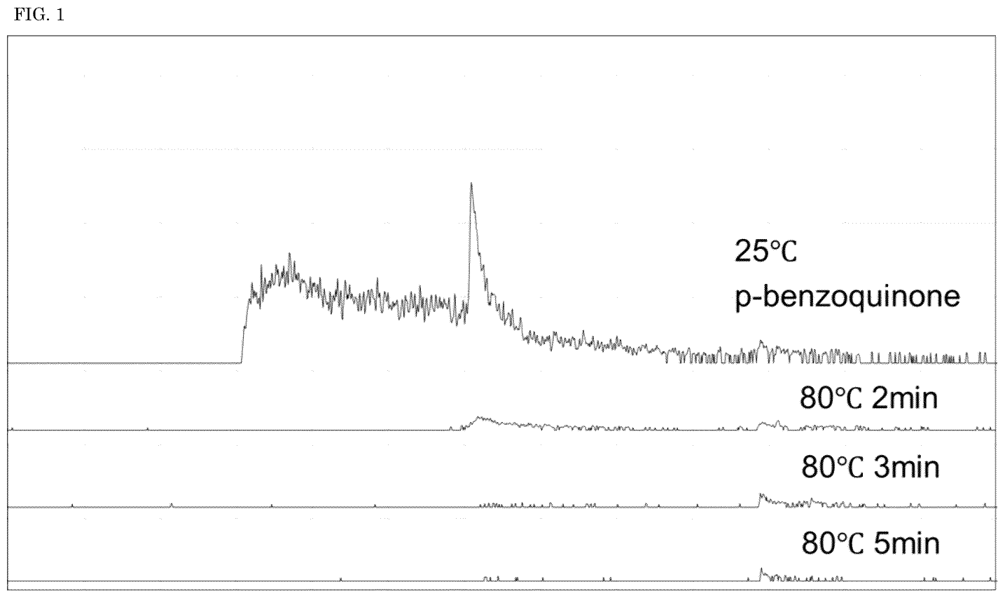

Using a gas chromatograph mass spectrometer (GC-MS) (e.g., GC-MSQP2010, manufactured by Shimadzu Corporation), the mass spectrum of p-benzoquinone at room temperature (about 25° C.) and the mass spectra of p-benzoquinone heat-treated at 80° C. for 2 minutes, 3 minutes, and 5 minutes, respectively, are measured. FIG. 1 shows the mass spectrum of 10 mg of p-benzoquinone at room temperature (about 25° C.) measured by GC-MS and the mass spectra of p-benzoquinone heat-treated at 80° C. for 2 minutes, 3 minutes, and 5 minutes, respectively, measured by GC-MA. As shown in FIG. 1, in the mass spectra of benzoquinone after heat-treated at 80° C. for the respective periods of time, certain peaks present in the mass spectrum of p-benzoquinone at room temperature (about 25° C.) no longer exist. Thus, it can be confirmed that p-benzoquinone sublimes through a heat treatment at 80° C. and no longer exists, demonstrating its sublimability.

As the polymerization inhibitor having sublimability (C), specifically, p-benzoquinone (manufactured by Fujifilm Wako Pure Chemical Industries, Ltd.) can be used as a polymerization inhibitor having sublimability at 80° C. or less.

The amount of component (C) contained in the resin composition is, relative to 100 parts by mass of the organic peroxide serving as component (B), preferably within a range of 0.1 parts by mass or more and 5.0 parts by mass or less, more preferably within a range of 0.2 parts by mass or more and 4.0 parts by mass or less, and still more preferably within a range of 0.3 parts by mass or more and 3.0 parts by mass or less. When the content of component (C) in the resin composition is within a range of 0.1 parts by mass or more and 5.0 parts by mass or less relative to 100 parts by mass of the component (B), the cleavage of the organic peroxide is suppressed at room temperature to suppress a radical polymerization reaction, making it possible to extend the pot life.

In the case where the resin composition further contains (D) electrically conductive particles, the electrically conductive particles are used to impart thermal conductivity and/or electrical conductivity to the resin composition. The resin composition containing the electrically conductive particles serving as component (D) can also be used as an electrically conductive adhesive used for bonding electronic components and the like. The electrically conductive particles serving as component (D) are particles having an average particle size within a range of 0.01 μm or more and 100 μm or less and an electrical conductivity of 10⁶ S/m or more. The electrically conductive particles serving as component (D) may be obtained by forming an electrically conductive material into particles, or may be obtained by coating a nucleus (core particle) with an electrically conductive material. The nucleus contained in an electrically conductive particle may be composed of an electrically non-conductive material as long as it is partially coated with an electrically conductive material. The electrically conductive particles serving as component (D) may be a metal powder or a coated powder. The average particle size of the electrically conductive particles can be measured by a laser diffraction scattering method, and the average particle size refers to the particle size at which the cumulative frequency in the volume-based particle size distribution is 50% (median diameter: D50).

Electrically conductive materials used for the electrically conductive particles (D) are not particularly limited as long as they impart thermal conductivity and/or electrical conductivity to the resin composition. As electrically conductive materials, gold, silver, nickel, copper, palladium, platinum, bismuth, tin, alloys thereof (in particular, bismuth-tin alloys, solders, etc.), aluminum, indium tin oxide, silver-coated copper, silver-coated aluminum, metal-coated glass spheres, silver-coated fibers, silver-coated resins, antimony-doped tin, tin oxide, carbon fiber, graphite, carbon black, and mixtures thereof can be mentioned.

Considering thermal conductivity and electrical conductivity, the electrically conductive material of the electrically conductive particles (D) is preferably at least one metal selected from the group consisting of silver, nickel, copper, tin, aluminum, silver alloys, nickel alloys, copper alloys, and aluminum alloys, more preferably at least one metal selected from the group consisting of silver, copper, and nickel, and still more preferably silver or copper, and particularly preferably contains silver.

In one aspect, the electrically conductive particles (D) are preferably silver particles. In another aspect, the electrically conductive particles (D) are preferably copper particles. As described above, the silver particles or copper particles may be a coated powder in which the surface of the nucleus (core particle) is at least partially coated with silver or copper.

As the electrically conductive particles (D), specifically, “EA 79613” and “K 79121P” (both manufactured by Metalor Technologies Japan), which are silver powders, can be used.

The amount of component (D) contained in the resin composition may be 95 parts by mass or less, or 92 parts by mass or less. In one aspect, the amount of electrically conductive particles (D) contained is, relative to 100 parts by mass of the total amount of the resin composition, preferably within a range of 10 parts by mass or more and 95 parts by mass or less, more preferably within a range of 20 parts by mass or more and 95 parts by mass or less, and still more preferably within a range of 50 parts by mass or more and 95 parts by mass or less, or may also be within a range of 70 parts by mass or more and 95 parts by mass or less.

The shape of the electrically conductive particles (D) is not particularly limited and may be any of spherical, amorphous, flaky (scaly), filament-like (needle-like), and dendritic shapes. The term “flaky” refers to a shape whose aspect ratio, which is expressed as “major axis/minor axis,” is 2 or more, and encompasses planar shapes such as plate-like and scaly shapes. With respect to the major axis and minor axis of each particle constituting the electrically conductive particles, based on an image obtained from a scanning electron microscope (SEM), the aspect ratio can be calculated from the average values of the major and minor axes of any 20 particles. “Major axis” refers to the longest diameter of line segments passing through the approximate center of gravity of a particle in a particle image obtained by SEM, and “minor axis” refers to the shortest diameter of line segments passing through the approximate center of gravity of a particle in a particle image obtained by SEM. The electrically conductive particles (D) may include particles of different shapes.

In the case where the electrically conductive particles (D) are silver particles, the silver particles preferably have a tap density of 1.5 g/cm³ or more, and more preferably within a range of 2.0 g/cm³ or more and 6.0 g/cm³ or less. When the tap density of the silver particles is too low, such silver particles cannot be dispersed at a relatively high density in the resin composition, and the electrical conductivity of the resulting cured product is likely to decrease. When the tap density of the silver particles is too high, such silver particles are prone to separation and precipitation in the resin composition, and the electrical conductivity may decrease. The tap density can be measured in accordance with JIS Z2512, Metal Powder-Tap Density Measurement Method.

In the case where the electrically conductive particles (D) are silver particles, from the viewpoint of imparting electrical conductivity to the cured product and from the viewpoint of handleability considering the flowability of the resin composition, the average particle size (D50) is preferably within a range of 0.05 μm or more and 50 μm or less, more preferably within a range of 0.1 μm or more and 20 μm or less, and still more preferably within a range of 0.1 μm or more and 15 μm or less.

In the case where the electrically conductive particles (D) are silver particles, the specific surface area is preferably 4.0 m2/g or less, and more preferably within a range of 0.1 m²/g or more and 3.0 m2/g or less. The specific surface area can be measured by the BET method. When the specific surface area of the silver particles is too large, the viscosity of the resin composition increases, and the handleability may decrease. When the specific surface area of the silver particles is too small, the contact area between the silver particles decreases, and the electrical conductivity may decrease.

The resin composition needs to contain the component (A), the component (B), and the component (C), and may further contain the component (D). It may also contain components other than the component (A), the component (B) and the component (C), or may contain no components other than the component (A), the component (B), the component (C) and the component (D). The resin composition may be composed only of the component (A), the component (B), and the component (C), or may also be composed only of the component (A), the component (B), the component (C), and the component (D).

Without interfering with the effects of the present invention or in order to improve the effects of the present invention, the resin composition may contain at least one additive selected from the group consisting of inorganic pigments, organic pigments, silane coupling agents, leveling agents, thixotropic agents, insulating particles, interface treatment agents such as coupling agents, dyes, plasticizers, defoamers, foam breakers, and antioxidants.

The content of additive in the resin composition may be, relative to 100 mass % of the resin composition, 10.0 mass % or less, 8.0 mass % or less, or 5.0 mass % or less. The content of additive in the resin composition may be 0.10 mass % or more, 0.20 mass % or more, 0.30 mass % or more, or 0.50 mass % or more.

### Method for Producing Resin Composition

The resin composition can be produced by mixing the component (A), the component (B), and the component (C), as well as the component (D) as necessary. The resin composition may also be produced by mixing the components together with additives as necessary. The method for producing the resin composition is not particularly limited. The resin composition can be produced by mixing the raw materials for the respective components using a mixer such as a Henschel mixer, a roll mill, or a three-roll mill. The components of the resin composition may be mixed simultaneously, or it is also possible that some of the components are mixed first, and the rest is mixed later. In addition, the resin composition may also be produced using an appropriate combination of the above apparatuses.

The resin composition preferably exhibits curability when cured at 80° C. for 60 minutes. The curability can be confirmed visually or by touch as described later in the method for evaluating curability.

The resin composition preferably has a pot life of 24 hours or more, more preferably has a pot life of 48 hours or more, and still more preferably has a pot life of 72 hours or more. “Pot life” refers to the period of time during which a resin composition remains usable after the preparation of the resin composition. Immediately after the preparation of a resin composition and after the resin composition was allowed to stand at ambient temperature (about 25° C.) for a predetermined period of time, the viscosity was measured using a Brookfield RVT viscometer (spindle: SC4-14 spindle, measurement temperature: 25° C.) at a rotation speed of 10 rpm, and, taking the viscosity of the resin composition immediately after preparation as 1.0, the rate of change in viscosity of the resin composition after being allowed to stand for a predetermined period of time was calculated as the thickening rate. The period of time it took for the thickening rate to reach 1.5 or more was expressed as the pot life time. A large thickening rate value indicates that the viscosity of the resin composition increases with time. In addition, a small thickening rate indicates that the change in viscosity with time is small. The pot life can be adjusted by the blending amounts of component (B) and component (C) in the resin composition.

### Method for Supplying Resin Composition

The resin composition can be supplied using a jet dispenser, an air dispenser, or the like. In addition, it can be supplied by known coating methods (dip coating, spray coating, bar coater coating, gravure coating, reverse gravure coating, spin coater coating, etc.) and known printing methods (lithographic printing, carton printing, metal printing, offset printing, screen printing, gravure printing, flexographic printing, inkjet printing, etc.).

### Curing Conditions for Resin Composition

The resin composition can be cured by heating at 40° C. or more and 120° C. or less, for example. The curing temperature of the resin composition is preferably within a range of 40° C. or more and 120° C. or less, and more preferably within a range of 50° C. or more and 100° C. or less. The heating time for curing the resin composition is preferably 15 minutes or more and 4 hours or less, and more preferably 30 minutes or more and 2 hours or less.

### Cured Product Obtained by Curing Resin Composition

As a result of curing the resin composition, a cured product obtained by curing the resin composition is obtained. The cured product obtained by curing the resin composition at 80° C. for 60 minutes has a room temperature elastic modulus preferably within a range of 0.005 GPa or more and 7.0 GPa or less, more preferably within a range of 0.05 GPa or more and 6.0 GPa or less, and still more preferably within a range of 0.1 GPa or more and 5.0 GPa or less. “Room temperature elastic modulus” refers to the degree of flexibility at room temperature that a cured product of a resin composition exhibits. It can be said that the lower the room temperature elastic modulus, the higher the flexibility. As shown in the measurement method in the Examples described later, the room temperature elastic modulus can be measured from a sample coating film having a predetermined thickness obtained by curing a resin composition using a viscoelasticity measuring apparatus (DMA) (e.g., DMA7100, manufactured by Hitachi High-Tech Science Corporation). The room temperature elastic modulus of a cured product of the resin composition can be adjusted by the molecular weight and blending amount of the component (A).

### Semiconductor Device

The resin composition can be suitably used for forming an interlayer insulating film of a semiconductor device, for forming a protective layer, and for an electrically conductive adhesive. For example, in the case where the resin composition is used as an electrically conductive adhesive in a semiconductor device, the semiconductor device includes a cured product obtained by curing the resin composition.

### Electronic Component

The resin composition can be suitably used as an electrically conductive adhesive in an electronic component, etc. For example, in the case where the resin composition is used as an electrically conductive adhesive in an electronic component, the electronic component includes a cured product obtained by curing the resin composition. The semiconductor device including the resin composition and a cured product thereof can be used as an electronic component of an electronic device such as a mobile phone, a smartphone, a laptop computer, a tablet terminal, or a camera module, etc.

### Examples

Hereinafter, the present invention will be described in more detail with reference to examples. The present invention is not limited to these examples. In the following examples and comparative examples, the numbers indicating the blending proportions of the components contained in the resin composition are in parts by mass unless otherwise noted.

### Component (A): Radically Polymerizable Curable Resin

A-1: Light Acrylate PO-A (phenoxyethyl acrylate, manufactured by Kyoeisha Chemical Co., Ltd.)
A-2: FA-513AS (dicyclopentanyl acrylate, Showa Denko Materials Co., Ltd.)
A-3: HEAA (hydroxyethyl acrylamide, KJ Chemicals Corporation)
A-4: BMI-1500 (bismaleimide resin, manufactured by Designer Molecules)
A-5: UN-6200 (urethane acrylate oligomer, weight average molecular weight (Mw): 6,500, manufactured by Negami Chemical Industrial Co., Ltd.)
A-6: MBA-2CZ (urethane acrylate oligomer, weight average molecular weight (Mw): 1,600, Negami Chemical Industrial Co., Ltd.)
A-7: UV-3000B (urethane acrylate oligomer, weight average molecular weight (Mw): 18,000, manufactured by Mitsubishi Chemical Corporation)
A-8: UN-3320HA (urethane acrylate oligomer, weight average molecular weight (Mw): 1,500, manufactured by Negami Chemical Industrial Co., Ltd.) Component (B): Organic peroxide
B-1: PEROYL TCP (peroxydicarbonate, 10-hour half-life temperature (T10): 40.8° C., manufactured by NOF Corporation)
B-2: Luperox 810 (1,1,3,3-tetrabutyl peroxydecanoate, 10-hour half-life temperature (T10): 44° C., manufactured by ARKEMA Yoshitomi, Ltd.)
B-3: Luperox 546 (t-amyl peroxydecanoate, 10-hour half-life temperature (T10): 46° C., ARKEMA Yoshitomi, Ltd.)
B-4: Luperox 10 (t-butyl peroxydecanoate, 10-hour half-life temperature (T10): 48° C., manufactured by ARKEMA Yoshitomi, Ltd.)
B-5: PEROCTA O (1,1,3,3-tetramethylbutyl peroxy-2-ethylhexanoate, 10-hour half-life temperature (T10): 65.3° C., manufactured by NOF Corporation) Component (C): Polymerization inhibitor having sublimability
C-1: p-Benzoquinone (parabenzoquinone, Fujifilm FUJIFILM Wako Pure Chemical Corporation), sublimable through a heat treatment at 80° C. for 2 minutes or more and 5 minutes or less.

### Component (C′): Polymerization Inhibitor

C′-2: N-nitroso-N-phenylhydroxylamine aluminum, manufactured by FUJIFILM Wako Pure Chemical Corporation)
C′-3: HQ (hydroquinone, FUJIFILM Wako Pure Chemical Corporation)
C′-4: TEMPO (2,2,6,6-tetramethyl-1-piperidinyloxy, radical, Koei Chemical Industry Co., Ltd.)

### Component (D): Electrically Conductive Particles

D-1: EA 79613 (silver powder, average particle size measured by a laser diffraction scattering method: 7 μm, BET specific surface area: 0.3 m2/g, tap density in accordance with JIS Z2512: 5.1 g/cm³, manufactured by Metalor Technologies Japan)
D-2: K 79121P (silver powder, average particle size measured by a laser diffraction scattering method: 7 μm, BET specific surface area: 2.3 m2/g, tap density in accordance with JIS Z2512: 2.7 g/cm³, manufactured by Metalor Technologies Japan)

### Examples 1 to 16, Comparative Examples 1 to 3

The materials for the component (A), component (B), component (C) or component (C′), and component (D) were blended to make the blending proportions shown in Tables 1 and 2, respectively, and stir-mixed using a three-roll mill to produce resin compositions of examples and comparative examples. In the tables, values without units are in “parts by mass”. In the tables, “Mw” represents “weight average molecular weight.” In the tables, “T10” represents “10-hour half-life temperature.” In addition, in the tables, the symbol “-” indicates that the corresponding component was not contained in the resin composition or was unmeasurable.

The resin compositions of examples and comparative examples and cured products obtained by curing the resin compositions were evaluated as follows. The results are shown in Tables 1 and 2.

### Curability at 80° C. For 60 Min

A 100-μm-thick tape was placed on a slide glass as a gap, and each resin composition was applied onto the slide to form a coating film. The resin composition was then cured at 80° C. for 60 minutes, thereby forming a cured product as a test piece. Whether the test piece had been cured was visually checked, and also whether any component derived from the resin composition would adhere to the finger was checked by touch. A test piece whose curing was confirmed visually and by touch was rated as “G (good)”, and a test piece whose curing was not confirmed visually or by touch was rated as “B (Bad)”.

### Pot Life

The viscosity of each of the resin compositions of examples and comparative examples immediately after preparation (within 3 hours after preparation) and the viscosity of each of the resin compositions of examples and comparative examples placed in a syringe after preparation (the resin composition was filled into a syringe immediately after preparation and hermetically sealed) and allowed to stand at ambient temperature (25° C.) were measured using a Brookfield RVT viscometer (spindle: SC4-14 spindle, measurement temperature: 25° C.) at a rotation speed of 10 rpm. Taking the viscosity of the resin composition immediately after preparation as 1.0, the change in viscosity of the resin composition after being allowed to stand at 25° C. was expressed as the thickening rate. The period of time it took for the thickening rate to reach 1.5 or more is shown in Table 1 or 2 as the pot life time. In the tables, a pot life time exceeding 72 hours is indicated as “>72”.

### Room Temperature Elastic Modulus

Onto a slide glass having attached thereto a Teflon® tape, each of the resin compositions of examples and comparative examples was applied to make a film thickness of 200±50 μm when cured, thereby forming a coating film. The resin composition was then cured in an air convection oven at 80° C. for 60 minutes to obtain a cured product. The cured product in the form of a coating film was peeled off from the slide glass having attached thereto the Teflon tape, and then cut with a utility knife into a size of 40 mm×5 mm to obtain a test piece of the cured product. The edge cut by the utility knife was smoothed with sandpaper. The obtained test pieces were measured in accordance with JIS C₆₄₈₁ using a viscoelasticity measuring apparatus (DMA) (DMA7100, manufactured by Hitachi High-Tech Science Corporation) under the following conditions.
Deformation mode: Tension
Measurement mode: Ramp
Frequency: 10 Hz
Strain amplitude: 5 μm
Minimum tension/pressure: 50 mN
Tension/compression force gain: 1.2
Initial force amplitude: 50 mN
Movement waiting time: 8 seconds
Creep waiting time factor: 0
Temperature: 25° C.

TABLE 1

| | | | Example 1 | Example 2 | Example 3 | Example 4 | Example 5 |
|---|---|---|---|---|---|---|---|
| (A) | A-1 | Light Acrylate PO-A (acrylate monomer) | 17.48 | 9.87 | 9.87 | 9.87 | 9.87 |
| Radically | A-2 | FA- [symbol] 13AS (acrylate monomer) | 5.24 | 2.96 | 2.96 | 2.96 | 2.96 |
| polymerizable | A-3 | HEAA (acrylate monomer) | — | 1.18 | 1.18 | 1.18 | 1.18 |
| curable resin | A-4 | BMI-1500 (bismaleimide) | — | [symbol] .5 [symbol] | 6.5 [symbol] | 6.5 [symbol] | 6.5 [symbol] |
| | A-5 | UN-8200 (Mw: [symbol] 500) (urethane acrylate oligomer) | — | 2.15 | 2.15 | 2.15 | 2.15 |
| | A-6 | MBA-2CZ (Mw: 1 [symbol] 00) (urethane acrylate oligomer) | — | — | — | — | — |
| | A-7 | UV-3000B (Mw: 1 [symbol] 000) (urethane acrylate oligomer) | — | — | — | — | — |
| | A-8 | UN-3320HA (Mw: 1500) (urethane acrylate oligomer) | — | — | — | — | — |
| (B) | B-1 | PEROYL T [symbol] P (T10: 40.8° C.) | — | — | 2.28 | — | — |
| Organic | B-2 | Luperox 810 (T10: 44° C.) | — | — | — | 2.28 | — |
| peroxide | B-3 | Luperox 54 [symbol] (T10: 46° C.) | 2.28 | 2.28 | — | — | — |
| | B-4 | Luperox 10 (T10: 48° C.) | — | — | — | — | 2.28 |
| | B-5 | PEROCTA O (T10: 65.3° C.) | — | — | — | — | — |
| (C) | C-1 | P-Benzoquinone (boiling | 0.030 | 0.030 | 0 030 | 0.030 | 0.030 |
| Sublimable | | point: none) | | | | | |
| polymerization | | | | | | | |
| inhibitor | | | | | | | |
| (C′) | C′-2 | N-nitroso-N-phenylhydroxylamine | — | — | — | — | — |
| Polymerization | | aluminum (boiling point: 168 to 170° C.) | | | | | |
| inhibitor | C′-3 | HQ (boiling point: 28 [symbol] ° C.) | — | — | — | — | — |
| | C′-4 | TEMPO (boiling point: 193° C.) | — | — | — | — | — |
| (D) | D-1 | EA 79613 (silver powder) | 37.87 | 37.87 | 37.87 | 37.87 | 37.87 |
| Electrically | D-2 | K 79121P (silver powder) | 37.87 | 37.87 | 37.87 | 37.87 | 37.87 |
| conductive | | | | | | | |
| particles | | | | | | | |

| | | | | | |
|---|---|---|---|---|---|
| Curability at 80° C. for [symbol] 0 minutes | G | G | G | G | G |
| Pot life [hours] | >72 | >72 | 48 | >72 | >72 |
| Room temperature elastic modulus [GPa] | 0.2 | 0.5 | 0.8 | 0.7 | 0.5 |

| | | | | Comparative | Comparative | Comparative |
|---|---|---|---|---|---|---|
| | | | Example 6 | Example 1 | Example 2 | Example 3 |
| (A) | A-1 | Light Acrylate PO-A (acrylate monomer) | 9.87 | 9.87 | 9.87 | 9.87 |
| Radically | A-2 | FA- [symbol] 13AS (acrylate monomer) | 2.96 | 2.96 | 2.96 | 2.96 |
| polymerizable | A-3 | HEAA (acrylate monomer) | 1.18 | 1.18 | 1.18 | 1.18 |
| curable resin | A-4 | BMI-1500 (bismaleimide) | 6.5 [symbol] | [symbol] .5 [symbol] | [symbol] .5 [symbol] | [symbol] .5 [symbol] |
| | A-5 | UN-8200 (Mw: [symbol] 500) (urethane acrylate oligomer) | 2.15 | 2.15 | 2.1 [symbol] | 2.15 |
| | A-6 | MBA-2CZ (Mw: 1 [symbol] 00) (urethane acrylate oligomer) | — | — | — | — |
| | A-7 | UV-3000B (Mw: 1 [symbol] 000) (urethane acrylate oligomer) | — | — | — | — |
| | A-8 | UN-3320HA (Mw: 1500) (urethane acrylate oligomer) | — | — | — | — |
| (B) | B-1 | PEROYL T [symbol] P (T10: 40.8° C.) | — | — | — | — |
| Organic | B-2 | Luperox 810 (T10: 44° C.) | — | — | — | — |
| peroxide | B-3 | Luperox 54 [symbol] (T10: 46° C.) | — | 2.28 | 2.28 | 2.28 |
| | B-4 | Luperox 10 (T10: 48° C.) | — | — | — | — |
| | B-5 | PEROCTA O (T10: 65.3° C.) | 2.28 | — | — | — |
| (C) | C-1 | P-Benzoquinone (boiling | 0.030 | — | — | — |
| Sublimable | | point: none) | | | | |
| polymerization | | | | | | |
| inhibitor | | | | | | |
| (C′) | C′-2 | N-nitroso-N-phenylhydroxylamine | — | 0.030 | — | — |
| Polymerization | | aluminum (boiling point: 168 to 170° C.) | | | | |
| inhibitor | C′-3 | HQ (boiling point: 28 [symbol] ° C.) | — | — | 0.030 | — |
| | C′-4 | TEMPO (boiling point: 193° C.) | — | — | — | 0.030 |
| (D) | D-1 | EA 79613 (silver powder) | 37.87 | 37.87 | 37.87 | 37.87 |
| Electrically | D-2 | K 79121P (silver powder) | 37.87 | 37 87 | 37.87 | 37.87 |
| conductive | | | | | | |
| particles | | | | | | |

| | | | | |
|---|---|---|---|---|
| Curability at 80° C. for [symbol] 0 minutes | G | B | G | B |
| Pot life [hours] | >72 | 72 | 12 | >72 |
| Room temperature elastic modulus [GPa] | 0.4 | 0.2 | 1.0 | — |

[symbol]

indicates data missing or illegible when filed

TABLE 2

| | | | Exam- | Exam- | Exam- | Exam- | Exam- | Exam- |
|---|---|---|---|---|---|---|---|---|
| | | | ple 7 | ple 8 | ple 9 | ple 10 | ple 11 | ple 12 |
| (A) | A-1 | Light Acrylate PO-A (acrylate monomer) | 9.87 | 9.87 | 9.87 | 9.87 | 9.87 | 10.30 |
| Radically | A-2 | FA-513AS (acrylate monomer) | 2.96 | 2.96 | 2.96 | 2.96 | 2.96 | 3.09 |
| polymerizable | A-3 | HEAA (acrylate monomer) | 1.18 | 1.18 | 1.18 | 1.18 | 1.18 | 1.23 |
| curable resin | A-4 | BMI-1500 (bismaleimide) | 6.56 | 6.56 | 6.56 | 6.56 | 6.56 | 6.85 |
| | A-5 | UN-8200 (Mw: [symbol] 500) (urethane acrylate oligomer) | — | — | — | 2.15 | 2.15 | 2.24 |
| | A-6 | MBA-2CZ (Mw: 1 [symbol] 00) (urethane acrylate oligomer) | — | 2.15 | — | — | — | — |
| | A-7 | UV-3000B (Mw: 18000) (urethane acrylate oligomer) | — | — | 2.15 | — | — | — |
| | A-8 | UN-3320HA (Mw: 1500) (urethane acrylate oligomer) | 2.15 | — | — | — | — | — |
| (B) | B-1 | PEROYL T [symbol] P (T10: 40.8° C.) | — | — | — | — | — | — |
| Organic | B-2 | Luperox 810 (T10: 44° C.) | — | — | — | — | — | — |
| peroxide | B-3 | Luperox 54 [symbol] (T10: 46° C.) | 2.28 | 2.28 | 2.28 | 2.28 | 2.28 | 1.32 |
| | B-4 | Luperox 10 (T10: 48° C.) | — | — | — | — | — | — |
| | B-5 | PEROCTA O (T10: 65.3° C.) | — | — | — | — | — | — |
| (C) | C-1 | P-Benzoquinone (boiling | 0.030 | 0.030 | 0.030 | 0.017 | 0.084 | 0.030 |
| Sublimable | | point. none) | | | | | | |
| polymerization | | | | | | | | |
| inhibitor | | | | | | | | |
| (C′) | C′-2 | N-nitroso-N-phenylhydroxylamine aluminum (boiling | — | — | — | — | — | — |
| Polymerization | | point: 168 to 170° C.) | | | | | | |
| inhibitor | C′-3 | HQ (boiling point: 288° C.) | — | — | — | — | — | — |
| | C′-4 | TEMPO (boiling point: 193° C.) | — | — | — | — | — | — |
| (D) | D-1 | EA 79 [symbol] 13 (silver powder) | 37.87 | 37.87 | 37.87 | 37.87 | 37.87 | 37.87 |
| Electrically | D-2 | K 79121P (silver powder) | 37.87 | 37.87 | 37.87 | 37.87 | 37.87 | 37.87 |
| conductive | | | | | | | | |
| particles | | | | | | | | |

| | | | | | | |
|---|---|---|---|---|---|---|
| Curability at 80° C. for [symbol] 0 minutes | G | G | G | G | G | G |
| Pot life [hours] | 72 | 72 | >72 | 72 | >72 | >72 |
| Room temperature elastic modulus [GPa] | 5.0 | 3.0 | 0.3 | 0.7 | 0.5 | 0.4 |

| | | | Exam- | Exam- | Exam- | Exam- |
|---|---|---|---|---|---|---|
| | | | ple 13 | ple 14 | ple 15 | ple 16 |
| (A) | A-1 | Light Acrylate PO-A (acrylate monomer) | 7.98 | 10.68 | 8.13 | 39.74 |
| Radically | A-2 | FA-513AS (acrylate monomer) | 2.39 | 3.20 | 2.44 | 11.92 |
| polymerizable | A-3 | HEAA (acrylate monomer) | 0.95 | 1.28 | 0.97 | 4.75 |
| curable resin | A-4 | BMI-1500 (bismaleimide) | 5.30 | 7.10 | 5.40 | 26.41 |
| | A-5 | UN-8200 (Mw: [symbol] 500) (urethane acrylate oligomer) | 1.74 | 2.33 | 1.77 | 8.66 |
| | A-6 | MBA-2CZ (Mw: 1 [symbol] 00) (urethane acrylate oligomer) | — | — | — | — |
| | A-7 | UV-3000B (Mw: 18000) (urethane acrylate oligomer) | — | — | — | — |
| | A-8 | UN-3320HA (Mw: 1500) (urethane acrylate oligomer) | — | — | — | — |
| (B) | B-1 | PEROYL T [symbol] P (T10: 40.8° C.) | — | — | — | — |
| Organic | B-2 | Luperox 810 (T10: 44° C.) | — | — | — | — |
| peroxide | B-3 | Luperox 54 [symbol] (T10: 46° C.) | 6.50 | 2.47 | 1.88 | 9.18 |
| | B-4 | Luperox 10 (T10: 48° C.) | — | — | — | — |
| | B-5 | PEROCTA O (T10: 65.3° C.) | — | — | — | — |
| (C) | C-1 | P-Benzoquinone (boiling | 0.030 | 0.030 | 0.030 | 0.12 |
| Sublimable | | point. none) | | | | |
| polymerization | | | | | | |
| inhibitor | | | | | | |
| (C′) | C′-2 | N-nitroso-N-phenylhydroxylamine aluminum (boiling | — | — | — | — |
| Polymerization | | point: 168 to 170° C.) | | | | |
| inhibitor | C′-3 | HQ (boiling point: 288° C.) | — | — | — | — |
| | C′-4 | TEMPO (boiling point: 193° C.) | — | — | — | — |
| (D) | D-1 | EA 79 [symbol] 13 (silver powder) | 37.87 | 35.00 | 46.00 | — |
| Electrically | D-2 | K 79121P (silver powder) | 37.87 | 35.00 | 46.00 | — |
| conductive | | | | | | |
| particles | | | | | | |

| | | | | |
|---|---|---|---|---|
| Curability at 80° C. for [symbol] 0 minutes | G | G | G | G |
| Pot life [hours] | 72 | >72 | >72 | >72 |
| Room temperature elastic modulus [GPa] | 1.0 | 0.3 | 1.9 | 0.008 |

[symbol]

indicates data missing or illegible when filed

As shown in Tables 1 and 2, each of the resin compositions of Examples 1 to 16 exhibited good curability when heated at 80° C. for 60 minutes, and the pot life was as long as 72 hours or more. In addition, the cured product obtained by curing each of the resin compositions of Examples 1 to 16 at 80° C. for 60 minutes had a room temperature elastic modulus within a range of 0.008 GPa or more and 5.0 GPa or less and had excellent flexibility.

In the resin composition of Comparative Example 1, because the polymerization inhibitor had no sublimability, the resin composition was not completely cured by heating at 80° C. for 60 minutes and partially remained uncured, exhibiting poor curability. In the resin composition of Comparative Example 2, because the polymerization inhibitor had no sublimability, the pot life was as short as 12 hours, exhibiting poor handleability. In the resin composition of Comparative Example 3, because the polymerization inhibitor had no sublimability, although the pot life was as long as 72 hours or more, the resin composition was not completely cured by heating at 80° C. for 60 minutes, exhibiting poor curability. In addition, the resin composition of Comparative Example 3 remained uncured and thus was not able to form a coating film, and the room temperature elastic modulus was unmeasurable.

### INDUSTRIAL APPLICABILITY

The resin composition according to the present invention can be used for a semiconductor device. The resin composition, cured product obtained by curing the resin composition, and semiconductor device including the cured product according to embodiments of the present invention can be used for electronic components of electronic devices such as mobile phones, smartphones, laptop computers, tablet terminals, and camera modules.

1. A resin composition comprising:
(A) a radically polymerizable curable resin;
(B) an organic peroxide; and
(C) a polymerization inhibitor having sublimability.

2. The resin composition according to claim 1, further comprising (D) electrically conductive particles.

3. The resin composition according to claim 1, wherein the organic peroxide (B) includes at least one member selected from the group consisting of dialkyl peroxides, peroxyesters, peroxymonocarbonates, diacyl peroxides, peroxydicarbonates, and peroxyketals.

4. The resin composition according to claim 1, wherein the organic peroxide (B) has a 10-hour half-life temperature of 70° C. or less.

5. The resin composition according to claim 1, wherein the radically polymerizable curable resin (A) contains a compound having a (meth)acryloyl group.

6. The resin composition according to claim 1, wherein the radically polymerizable curable resin (A) contains a bismaleimide compound.

7. The resin composition according to claim 1, wherein the polymerization inhibitor having sublimability (C) includes p-benzoquinone.

8. A cured product obtained by curing the resin composition according to claim 1.

9. A cured product obtained by curing the resin composition according to claim 1 at 80° C. for 60 minutes,
the cured product having a room temperature elastic modulus within a range of 0.005 GPa or more and 7.0 GPa or less.

10. A semiconductor device comprising the cured product according to claim 9.

11. An electronic component comprising the cured product according to claim 9.
